(19) United States
(12) Patent Application Publication
(10) Pub. No.: US 2026/0063819 A1
(43) Pub. Date: Mar. 5, 2026

(54) DEVICE FOR INJECTING A CURRENT AT A MAGNETIC AND/OR METAL STRUCTURE TO GENERATE A SIGNAL MEASURABLE BY MAGNETOMETRIC SENSORS AND ASSOCIATED MAPPING DEVICE FOR CHECKING THE CONDITION AND/OR GEOLOCATION OF SAID STRUCTURE

(71) Applicant: SKIPPER NDT, Pau (FR)

(72) Inventor: Vincent Le Gouis, Paris (FR)

(21) Appl. No.: 19/318,949

(22) Filed: Sep. 4, 2025

(30) Foreign Application Priority Data
Sep. 5, 2024 (FR) 2409416

(51) Int. Cl. G01V 3/165; H03H 7/01

(52) U.S. Cl. CPC G01V 3/165; H03H 7/0138

(57) ABSTRACT

The present invention relates to a device for injecting a current at a magnetic and/or metal structure to generate a signal measurable by magnetometric sensors, as well as an associated mapping device. The injection device includes: means for connecting at input to a power supply, means for connecting at output to electrical connection points of said structure, a stage for converting the voltage supplied by the power supply comprising an inverter and processing means for generating a direct voltage at output according to at least one determined frequency. A filtering stage controls the envelope of the current injected at the structure making it possible to obtain a response of the structure measurable by magnetometric sensors.

### TECHNICAL FIELD

The present invention mainly relates to a device for injecting a current at a magnetic and/or metal structure to generate a signal measurable by magnetometric sensors. The invention will find its application in the location of pipeline type pipes, in particular for liquid or gas transfer. The invention may also be used for the detection and geolocation of other types of structures or in geophysics type research. The invention may also be used in the external inspection of structures both for inspecting the integrity of the structure and for evaluating the magnetic connection between two nearby structures.

### TECHNOLOGICAL BACKGROUND

Various detection methods using magnetometers for detecting non-visible structures are known. Among these methods, there is a first “passive” method wherein the sensors record the magnetic signal transmitted by the ground comprising the structures to be detected, and a second “active” method wherein a current is injected into the structure to measure the response of the structure when live.

The present invention is in the field of detection from the active method. To implement this active method, a current is injected at a known position point of the structure. In the case of pipes or pipelines, the potential tapping points or offtake terminals installed when laying the pipe or pipeline are generally used.

During the injection, measurements are taken in the conventional way, in particular by scanning the sector to be inspected, from magnetometers, then a 2D or 3D geolocation map is generated from the data collected, combining the measurements and the positioning of the sensors.

Until now, the current injection has been performed by standard current generators whose purpose is simply to convert a current at input in order to supply energy to an electrical receiver. The characteristics of the current generated by this type of generator are inaccurate and inconsistent; therefore the use of these current generators results in errors for the measurements of the sensors and their operation.

More specifically, one of the problems of these generators is that, in particular, the current injected is neither sufficient nor stable during injection.

Another problem is that the generators cannot optimally vary the injection frequency; moreover the spectrum of these frequencies is too wide and again generates random responses of the structures, resulting in unusable measurements or measurement anomalies.

Another problem is that the generators send, after adjustment, a voltage that cannot be modified according to different parameters, such as the dimensions of the pipeline, or according to the measurements obtained by the sensors or possible interference in the field.

As a result, operators have to manually perform many tests with the current generators in order to obtain results, which results are random and of insufficient quality.

Finally, according to another aspect, the injection points in the structure to be examined are, in most case studies, outdoors and exposed to the elements. The standard generators used in these conditions are not suitable; in particular, moisture or impacts cause drifts in frequency of the injected current that cannot be compensated in the field.

### Technical Problem to be Solved

A technical problem that the present invention proposes to solve is to provide a new injection device wherein the characteristics of the injected current ensure a stability of the response of the structure allowing exploitation of the signals received by the sensors.

Another problem that the present invention proposes to solve is to propose an injection device allowing making it possible to generate current modifications according to the characteristics of the underground structure and/or the magnetic response of the structure.

Another problem that the present invention proposes to solve is to associate in real time the generation of the current according to the conditions of measurement of the sensors making it possible to optimise the data deriving from the measurements of the sensors, and consequently to improve the location of the structures and/or the diagnosis of the condition of the structures. Another problem that the present invention proposes to solve is to propose an injection device that is simple to implement, adapted to the conditions of the ground, and making it possible to generate current voltages up to 150 V at precise and adjustable frequencies.

### SUMMARY OF THE PRESENT INVENTION

The present invention relates to a device for injecting a current at a magnetic and/or metal structure to generate a signal measurable by magnetometric sensors.

The invention is intended to be implemented in single-phase electrical installations.

The invention may be portable, or semi-portable, in particular using carriers such as a carriage or a drone.

According to the invention, the device for injecting a current comprises:
input connection means to a power supply,
output connection means to electrical connection points of said structure,
a stage for converting the voltage supplied by the power supply comprising an inverter and processing means for generating a direct voltage at output according to at least one determined frequency,
a filtering stage for controlling the envelope of the current injected at the structure making it possible to obtain a response from the structure measurable by magnetometric sensors.

Advantageously, the filtering means may comprise a first filtration, arranged between the power supply and the conversion stage, said first filtration comprising at least one capacitor making it possible to limit the variations of the power supply and to regulate the output power.

Preferably, the first filtration comprises a series of capacitors from 1 to 10 capacitors with capacities of 100 to 500 μF making it possible to limit variations in the amplitude of the output signal to 0.2%.

Quite preferably, the first filtration comprises a series of 4 capacitors with capacities of 350 to 500 μF making it possible to limit variations in the amplitude of the output signal to 0.2%.

Advantageously, the filtering means may include a second filtration comprising a frequency filter allowing the selection of at least one fundamental harmonic.

Preferably, the frequency filter is an LC low-pass differential filter, with the inductances of the differential filter smoothing the current and the capacitor limiting power surges.

Preferably, the second filtration makes it possible to select at least two fundamental frequencies simultaneously and/or alternately.

In preferred variants of the invention, the connection means, the filtering stage and the conversion stage are arranged in a case integrating mechanical stabilisation means comprising foam and shock absorbers making it possible to stabilise in temperature and/or hydrometry and/or position the electronic components of said control device.

The present invention furthermore relates to a mapping method for the checking the condition and/or geolocation of an underground, semi-underground or submerged structure comprising a metallic or magnetic material. The mapping device according to the invention comprises a current injection device, a carrier equipped with magnetometric sensors and position sensors, said injection device and said carrier comprising communication and control means for modifying the current to be injected according to data transmitted by the carrier to the current injection device.

Preferably, the communication and control means of said mapping device associated with the processing means make it possible to modify the parameters in frequency and/or intensity of the current to be injected.

Quite preferably, the communication and control means of said mapping device enable the transmission of navigation commands from the injection device to the vehicle.

### Definitions

According to the present invention, the term magnetic or metallic material, in this application, refers to any type of conductive material generating a magnetic field after injecting a current, and in particular includes ferromagnetic type materials.

According to the present invention, the term carrier, in this application, refers to a device for supporting and moving the sensors. It may in particular be, but is not limited to, a vehicle such as a carriage, in particular a motorised one, or an aerial drone equipped with a sensor support ramp.

### BRIEF DESCRIPTION OF THE FIGURES

Other features and advantages of the present invention will become apparent from the description of the particular and non-limiting embodiments of the present invention hereinafter, with reference to appended FIGS. 1 to 4, wherein:

FIG. 1 schematically illustrates an injection device according to a first embodiment in accordance with the invention,

FIG. 2 represents an example electronic diagram of the first filtration according to the invention,

FIG. 3 schematically illustrates an example injection device wherein the conversion stage according to the invention is detailed,

FIG. 4 represents a schematic example of embodiment of the mapping device according to the invention

FIG. 5 schematically illustrates in more detail the injection device according to the first embodiment according to the invention.

### DESCRIPTION OF EXAMPLES OF EMBODIMENTS

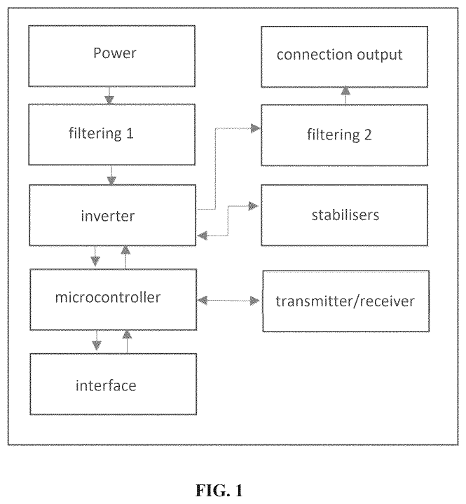

FIG. 1 and FIG. 5 illustrate an injection device according to a first embodiment. More precisely, the injection device schematically comprises means for connecting at input to a power supply. These means are integrated in the “power supply input” block of FIG. 1.

The “power supply input” block of FIG. 1 corresponding to the “A/AC-DC” block of FIG. 5, may for example comprise at least one of: a high-frequency UPS, a rectifier, an LC filter. When present, the LC filter of the “power supply input” block allows the implementation of the Zero-Voltage-Switching technique and allows a reduction of losses.

These connection means may be implemented in a standard manner to allow connection to a single-phase power source preferably between 115 and 230 V for frequencies of 47 to 63 Hz. The single-phase power source is illustrated in FIG. 5 by the “A/M” block.

The “stabiliser” and “transmitter/receiver” blocks are not shown in FIG. 5; indeed either of these blocks may optionally be implemented in this first embodiment of the invention.

The injection device further comprises a filtering stage. This filtering stage is carried out by means of two filters, comprising a first filter arranged at the “filtration 1” block between the “power supply input” block and the “inverter” block. This first filter comprises at least one capacitor making it possible to limit variations in the power supply and to regulate the output power.

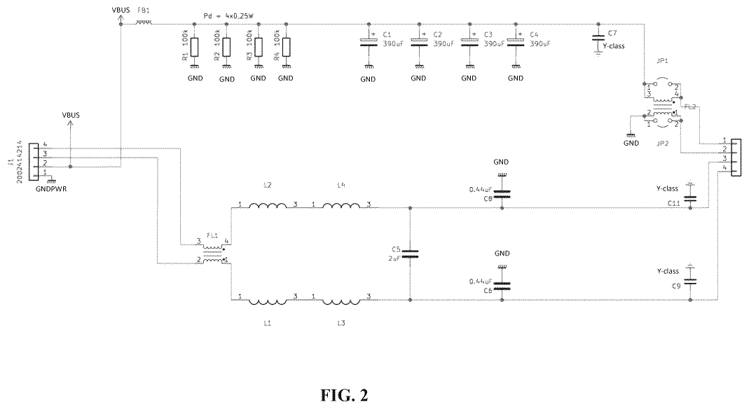

Referring this time to FIG. 2, an example of electrical diagram for implementing this first filter is shown.

The function of this first filter is to filter the output signal of the “power supply input” block. It limits power supply variations to provide a perfectly stable bus. It should be stated that this stable bus is necessary for the specific application of the present invention, namely the injection of a current to a structure in order to make it possible to examine the magnetic response of the structure.

Without this first filter, the bus would exhibit significant variations, resulting in significant variations in the envelope of the current injected into the structure. However, the sensors used for the magnetometry use the response of the structure that depends on this envelope.

In the absence of a stable bus, the current injected into the structure is not stable enough for the measurements of the magnetometric sensors to be usable. In particular, in order to be able to perform exploitable measurements, the applicant determined, according to the precision required by the algorithms, of the order of 1 μT, and the dynamics of the sensors, of the order of 250 μT, that the variation of the maximum permissible envelope was 0.2%.

This first filter also makes it possible to provide a peak power greater than the power supplied at the “power supply input” block output. This characteristic is particularly interesting because the instantaneous power having to be injected into the structures in order to obtain an effect measurable by the sensors is greater than that obtained by conventional electrical networks such as 230V at 50 Hz or 115V at 60 Hz, or by electrical power supplies whose other performances (weight, dimensions) are compatible with the application.

This feature makes it possible to deliver the necessary high powers, in particular greater than 2000 W, on large-sized structures or those with high electrical losses.

For this purpose, as shown in FIG. 2, the first filter is a DC filter comprising a set of capacitors allowing both control of the variation of the output voltage and the generation of power greater than that supplied by the network. This first filter filters the 216V bus at the output of the UHP-1500HV-230 power supply. In the example, it comprises four capacitors with capacities between 350 and 500 μF, and preferably 390 μF, i.e. 1.56 mF. This being said, other configurations of up to 10 capacitors are possible with varying capacities between 100 and 500 μF. This assembly, for an output signal at 10 Hz for 100 Vrms and 10 Arms, can generate at its peak, 14.2 A peak, i.e. 2016 W, and therefore more than what the power supply can provide.

The output power in a pipe representing a 10Ω load is as follows:

$$Pinsk , max = V rms * I rms * 2 = 100 * 10 * 2$$

$$Pinst max = 2000 W$$

In addition, this capacitor assembly makes it possible to limit variations in the amplitude of the output signal to 0.2%.

As shown in FIG. 1, the “inverter” and “microcontroller” blocks are found at the output of the “filtration 1” block

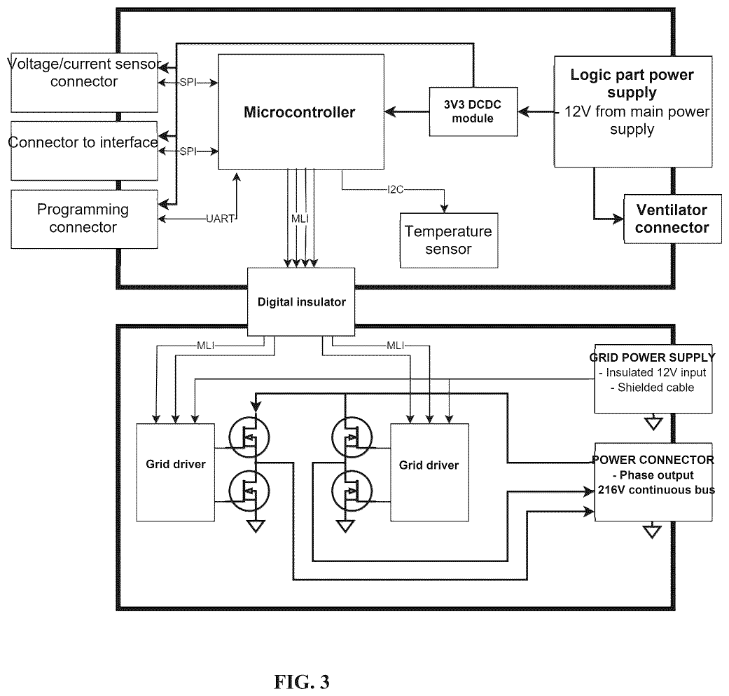

Referring this time to FIG. 3, a more detailed example is shown of the inverter and the microcontroller which respectively constitute the stage for converting the voltage supplied by the power supply and the processing means for generating a direct voltage at output according to at least one determined frequency.

As shown in FIG. 3, the inverter is of the Pur Sin type. The power part is fitted with an H-bridge whose principle is to connect the output to the 216V bus in a fraction of the time. Depending on the cut-off speed, the inverter can generate a voltage at the output which is a fraction of 216V. By varying this mean value according to a sinusoidal law, a signal is produced whose fundamental is at the desired output frequency and whose modulation is much higher, around 30 KHz.

The logic part consists of a microcontroller, a 3.3V power supply stage supplied by the auxiliary output of the main power supply, a temperature sensor, and connectors to the other boards of the system. Its mass is connected to earth so as to limit electromagnetic emissions. Both parts are electrically insulated and a digital insulator provides one-way communication.

Depending on the applications, the conversion stage may provide one or more output frequencies. The response of the structure to the injection of a current under several frequencies may make the measurements of the sensors more efficient, in particular if one of the frequencies generates a response in a frequency disturbed by the environment.

According to the invention, the microcontroller preferably controls the inverter according to pulse width modulation (PWM).

In the embodiment of FIG. 3, the inverter being of the Pur Sin type, the microcontroller controls it quite preferably according to sinusoidal pulse width modulation (SPWM). In such an embodiment, the “filtration 2” block makes it possible to extract the desired fundamental frequency from the output signal of the H-bridge.

To make it possible to generate several frequencies, the electronic board of the conversion stage comprises an 80 MHz clock and a temperature-compensated crystal which makes it possible to limit cycle-to-cycle variations. The processing means use the clock to generate different fundamental frequencies at the converter output.

The input signal of the second filter can thus have several fundamental frequencies lower than the frequency of the filter (1000 Hz) generated by the switching in the conversion stage.

Referring again to FIG. 1, it can be seen that the injection device further comprises an “interface” block and a “transmitter/receiver” block

The “interface” block conventionally comprises control means for the operator such as a keyboard and/or a screen.

The “transmitter/receiver” block comprises means for exchanging data between the injection device and the magnetometric sensors carried by the carriers. It is important to note that in a first embodiment, the injection device operates without communicating with the sensors. The various modifications to the current injected, for example frequencies or amplitude, are carried out by the operator, possibly after having collected and analysed the data of the sensors or by following a routine.

In this first embodiment, these communication means are therefore optional and thus the injection device may not comprise a “transmitter/receiver” block.

In a second embodiment, the injection device as shown in FIG. 1 comprises means of transmission/reception with the sensors of a vehicle. This embodiment is particularly interesting since it makes it possible to modify different parameters of the current injected according to the data from the sensors of the vehicle.

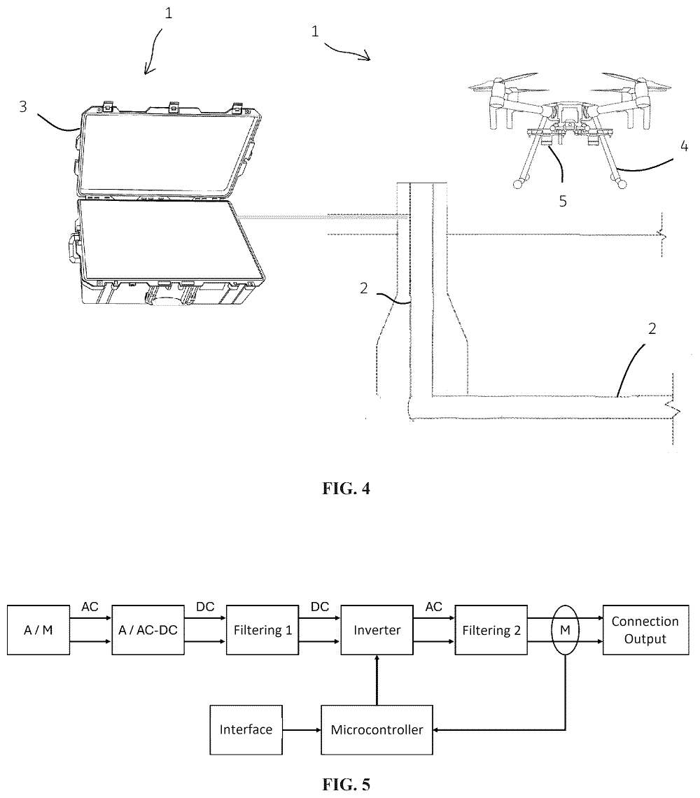

Referring to FIG. 4, an example embodiment of a mapping device 1 is shown schematically. This mapping device 1 may be used to check the condition and/or geolocation of an underground 2, semi-underground or submerged structure comprising a metallic or magnetic material.

This mapping device 1 comprises an injection device 3 and at least one carrier 4 equipped with magnetometric sensors 5 and position sensors 6. The injection device 3 and said carrier 4 comprise communication and control means (not represented in the appended FIG. 4). According to an advantageous feature of the invention, the data transmitted to the injection device 3 enable the processing means to send instructions to modify the current to be injected into the structure 2.

For example, when the data show a too weak response of the structure to the current injection, the instruction of the processing means may be to change the frequency and/or increase the current intensity.

For example, the position data can also be used to start or stop the current injection in particular according to the presence of the carrier 4 on the area to be inspected or outside this area.

As indicated above, the communication and control means associated with the processing means make it possible to modify the parameters in frequency and/or intensity of the current to be injected. It is also possible that the communication and control means will transmit information to the operator via the interface allowing it to act on the parameters of the injection device 3.

Conversely, in a third embodiment, combinable with the two other embodiments described above, the communication and control means enable the transmission of navigation commands from the injection device 3 to the carrier 4.

Referring again to FIG. 1, it can be seen that the injection device also comprises a “stabilisers” block. According to an advantageous feature of the invention, the connection means, the filtering stage and the conversion stage are arranged in a case integrating mechanical stabilisation means. These mechanical stabilisation means are used to protect the sensitive electronic components of the injection device. Advantageously, these mechanical stabilisation means comprise foam and shock absorbers making it possible to stabilise the temperature and/or hydrometry and/or position of the electronic components of said control device. The stabilisation means also comprise a sealed case to accommodate all the components of the current injection device.

According to the invention, the stage of the filtering means comprises a second filtration arranged at the “filtration 2” block shown in FIG. 1. The second filtration is obtained by a frequency filter allowing the selection of at least one fundamental harmonic.

Advantageously, the frequency filter is an LC low-pass differential filter, with the inductances of the differential filter smoothing the current and the capacitor limiting power surges. Thus, when the frequency filter is an LC low-pass differential filter, it provides protection against DC bus voltage peaks.

Advantageously, it is also provided that the second filtration makes it possible to select at least two fundamental frequencies simultaneously and/or alternately.

FIG. 5 illustrates the measurement M of the voltage and current, actually obtained at the output of the “filtration 2” block and which is supplied to the microcontroller by the current/voltage sensor whose connector is illustrated in FIG. 3, so as to maintain the stability of the current standard against changes in the impedances of the underground structures.

Referring to FIG. 1, it can be seen that the injection device further comprises a “connection output” block. In this “connection output” block, the means of connection at the output to electrical connection points of the structure are found.

These output connection means comprise a first output connectable to earth, and a second to an underground pipe. The charge is similar to a complex impedance in series with a battery linked to galvanic contact between steel and earth. The latter creates a voltage of approximately 2V between its terminals and an impedance of 1Ω to 15Ω depending on the type of soil and pipe.

The injection device as described therefore makes it possible to overcome the drawbacks of the current generators of the prior art by proposing features allowing precise control of the current parameters injected into the structure and, in an advantageous variant, control means according to the measurements taken by the sensors of the vehicle.

Of course, other features within the grasp of a person skilled in the art could also have been considered without for all that leaving the scope of the invention as defined in the following claims.

1. A device for injecting a current at a magnetic and/or metal structure to generate a signal measurable by magnetometric sensors comprising:
input connection means to a power supply,
output connection means to electrical connection points of said structure,
a stage for converting the voltage supplied by the power supply comprising an inverter and processing means for generating a direct voltage at output according to at least one determined frequency,
a filtering stage for controlling the envelope of the current injected at the structure making it possible to obtain a response from the structure measurable by magnetometric sensors.

2. The current injection device according to claim 1, wherein the filtering means comprise a first filtration, arranged between the power supply and the conversion stage, said first filtration comprising at least one capacitor making it possible to limit the variations of the power supply and to regulate the output power.

3. The current injection device according to claim 2, wherein the first filtration comprises a series of capacitors of 1 to 10 capacitors with capacities of 100 to 500 μF making it possible to limit variations in the amplitude of the output signal to 0.2%.

4. The current injection device according to claim 3, wherein the first filtration comprises a series of 4 capacitors with capacities of 350 to 500 μF making it possible to limit variations in the amplitude of the output signal to 0.2%.

5. The injection device according to claim 2, wherein the filtering means include a second filtration comprising a frequency filter allowing the selection of at least one fundamental harmonic.

6. The current injection device according to claim 5, wherein the frequency filter is an LC low-pass differential filter, with the inductances of the differential filter smoothing the current and the capacitor limiting power surges.

7. The current injection device according to claim 4, wherein the second filtration makes it possible to select at least two fundamental frequencies simultaneously and/or alternately.

8. The current injection device according to claim 1, wherein the connection means, the filtering stage and the conversion stage are arranged in a case integrating mechanical stabilisation means comprising foam and shock absorbers making it possible to stabilise in temperature and/or hydrometry and/or position the electronic components of said control device.

9. A mapping device for checking the condition and/or geolocation of an underground, semi-underground or submerged structure comprising a metallic or magnetic material comprising an injection device according to claim 1, a carrier equipped with magnetometric sensors and position sensors, said injection device and said carrier comprising communication and control means for modifying the current to be injected according to data transmitted by the vehicle to the control device.

10. The mapping device according to claim 9, wherein the communication and control means associated with the processing means make it possible to modify the parameters in frequency and/or intensity of the current to be injected.

11. The mapping device according to claim 9, wherein the communication and control means enable the transmission of navigation commands from the injection device to the vehicle.
